(19) United States
(12) Patent Application Publication
(10) Pub. No.: US 2010/0013533 A1
(43) Pub. Date: Jan. 21, 2010

(54) DIGITAL DELAY LINE AND APPLICATION THEREOF

(76) Inventors: Chen-Yi LEE, Hsinchu (TW); Jui-Yuan Yu, Hsinchu (TW); Juinn-Ting Chen, Hsinchu (TW)

Correspondence Address: Muncy, Geissler, Olds & Lowe, PLLC, P.O. BOX 1364, FAIRFAX, VA, 22038-1364, US

(21) Appl. No.: 12/390,776

(22) Filed: Feb. 23, 2009

(30) Foreign Application Priority Data
Jul. 18, 2008 (TW) 97127455

(51) Int. Cl. H03L 7/06; H03H 11/26

(52) U.S. Cl. 327/159; 327/261; 327/276

(57) ABSTRACT

A digital delay line includes a plurality of hysteresis-based delay cells electrically connected in series. These hystersis delay units in the hysteresis-based delay cells may be similar or different. All of the hysteresis delay units respectively have an inverter mode and a hesteresis mode. The delay and resolution of the hysteresis delay unit may be derived from the time difference in the inverter mode and hysteresis mode. Such a digital delay line applied to a digital phase locked loop may reduce consumption of area and power.

### BACKGROUND OF THE INVENTION

1. Field of the Invention

The present invention relates to a delay line and application thereof, and more particularly, to a delay line comprising hysteresis delay cells and its application in digital phase-locked loops.

2. Description of the Prior Art

The most difficult problems in application specific integrated circuit (ASIC) design often involve meeting system I/O timing demands. IC delays can vary by 200-400% over all voltage, temperature, and process conditions. If this delay can be controlled, systems can be designed which more fully exploit the innate performance capabilities of their semiconductor components. It is important to minimize on-chip clock distribution delay and total system clock skew in a system which uses ASICs in order to provide for safe data transfer between the ASICs. ASIC Phase Locked Loops (PLLs) are used most commonly to eliminate on-chip clock distribution delay. PLLs can eliminate delay in clock buffering by adding an adjustable delay which delays the output signal exactly one clock period relative to the input clock.

There are two primary types of PLLs: analog phase locked loops (APLLs); and digital phase locked loops (DPLLs). Some analog PLLs use a set delay chain to adjust delay and each element in the delay chain has its delay varied by analog bias voltages supplied by a phase detector. Digital phase locked loops do not adjust delays of any gates, but vary delays by adjusting how many delay steps are included in a delay chain. The delay chain comprises a plurality of inventers. The primary drawback of the DPLL is that the phase jitter is very high compared to the jitter of an APLL. In DPLL applications, the phase jitter is equal to the step size of the digital delay line. Thus, by making the step size of the digital delay line smaller, the effective phase jitter can be reduced resulting in more accurate phase locking capability.

### SUMMARY OF THE INVENTION

The present invention is directed to a delay line and its application in a digital circuit. The delay line comprises hysteresis delay cells to reduce the area of the delay line and power consumption.

The present invention is also directed to a delay line and its application in digital phase-locked loops. The delay line comprising various hysteresis delay cells is advantageous to due to design flexibility of the digital phase-locked loops.

Accordingly, one embodiment of the present invention provides a delay line, comprising a plurality of hysteresis delay cells connected in series, wherein each of the hysteresis delay cells comprises a hysteresis delay unit, and wherein the hysteresis delay units are configured for respectively comparing a first input voltage and a first threshold voltage to determine a first constant output voltage, and comparing a second input voltage and a second threshold voltage to determine a second constant output voltage, and wherein the first threshold voltage is different from the second threshold voltage, and the first constant output voltage is different from the second constant output voltage. Such a delay line may be applied to digital phase-locked loops, a digitally-controlled oscillator and a digitally-controlled hysteresis loops circuit.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a schematic diagram illustrating the output characteristics of hysteresis circuit applied to the present invention;

FIG. 2 is a block diagram illustrating a HDC applied to PLL in accordance with the present invention;

FIG. 3A is a schematic circuit in accordance with one embodiment of the present invention;

FIG. 3B is a schematic circuit in accordance with one embodiment of the present invention;

FIG. 4A is a schematic circuit in accordance with one embodiment of the present invention; and

FIG. 4B is a schematic circuit in accordance with one embodiment of the present invention.

### DETAILED DESCRIPTION OF THE INVENTION

The embodiments of the present invention are illustrated in reference to the drawings.

There are various examples configured for illustrating a hysteresis-based delay cell (HDC) as basis of a delay line. Such a delay line may be applied to, but not limited to, a digitally-controlled oscillator (DCO), all-digital phase-locked loops (ADPLL), all-digital delay-locked loops (ADDLL), all-digital multi-phase clock generator (ADMCG) and digital phase-locked loops based applications. Next, the spirit of the present invention is illustrated with the exemplary hysteresis-based delay cells without the limitation on components and connection hereafter.

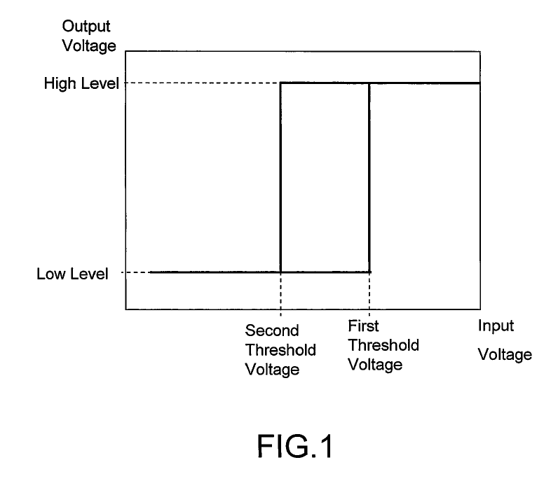

Referring to FIG. 1, the hysteresis delay unit is hysteresis-based including a circuit with a low level voltage as a first input voltage. When the first input voltage of the circuit reaches a first threshold voltage, an output voltage (first output constant voltage) is sharply inverted from a low level constant voltage to a high level constant voltage. Next, when the second input voltage of the circuit decreases to a second threshold voltage, an output voltage (second output constant voltage) is sharply inverted from a high level constant voltage to a low level constant voltage. The voltage difference in the first and second threshold voltages (non zero generally) is so-called hysteresis width. The setting of the hysteresis width prevents the noise voltage of elements from overlapping with the output voltage to result in vibration of the elements. Based on a specific range comprehended, HDCs are further defined as a very-large-scale HDC (VLHDC), large-scale HDC (LHDC), medium-scale HDC (MHDC) and small-scale HDC (SHDC). The unit applied to the exemplary delay line may be implemented with the combination of various aforementioned HDS.

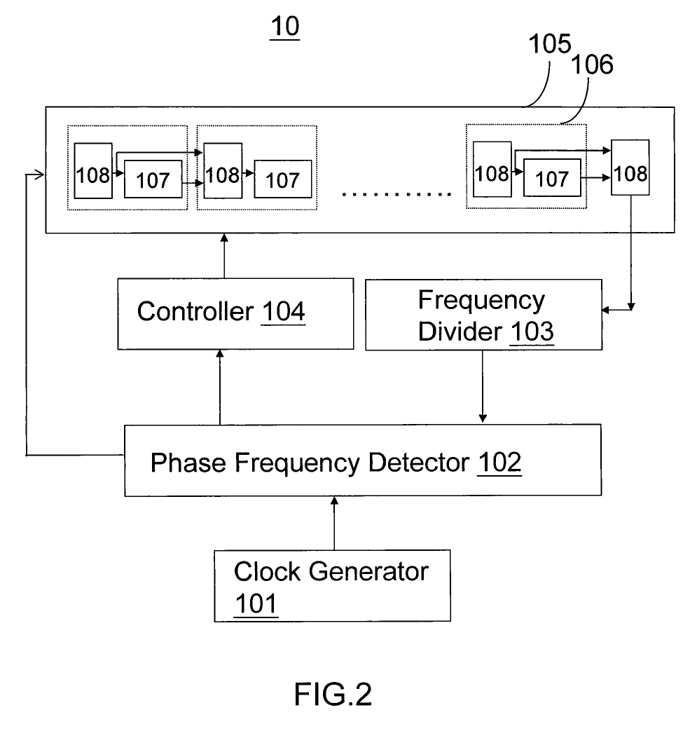

FIG. 2 is a block diagram illustrating a HDC applied in a PLL 10 in accordance with the present invention. In one example, the PLL 10 includes a clock generator 101, a phase frequency detector 102 (PFD), a frequency divider 103, a controller 104 and a digitally-controlled delay line 105. The exemplary clock generator 101 provides the phase frequency detector 102 with a precise system clock. The exemplary phase frequency detector 102 is configured for detecting a feedback clock processed by the clock generator 101 and the frequency divider 103 and transiting a feedback to the controller 104. The controller 104 is configured for generating a control signal on the basis of the feedback from the phase frequency detector 102 and transiting the control signal to the digitally-controlled delay line 105. The digitally-controlled delay line 105 may be consisted of a plurality of hysteresis delay cells 106. In the embodiment, the hysteresis delay cells 106 include respectively, for example but not limited to, a path selector 108 and a hysteresis delay unit 107.

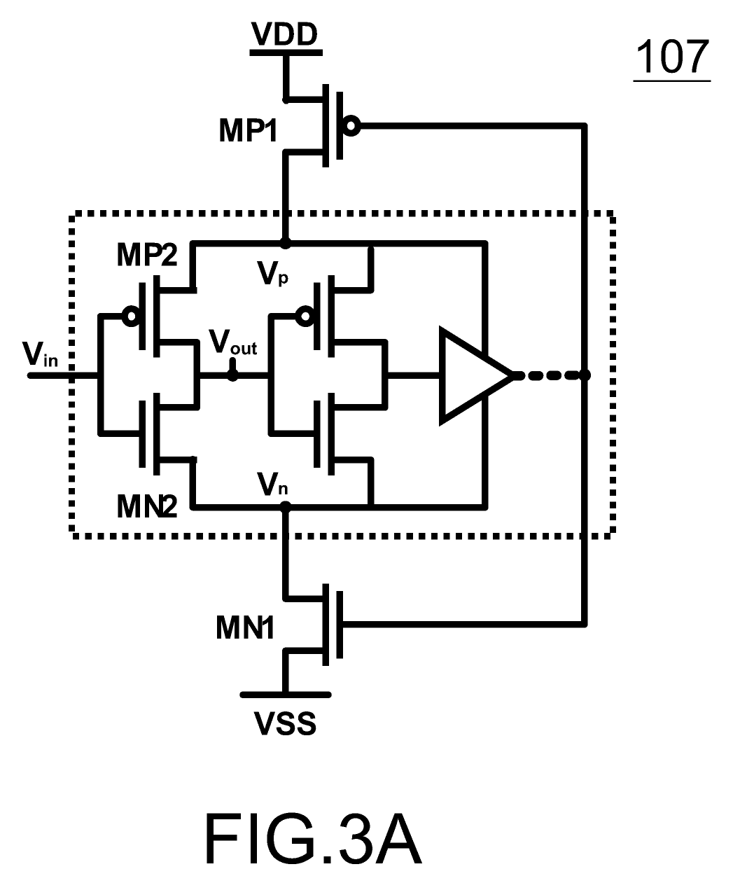

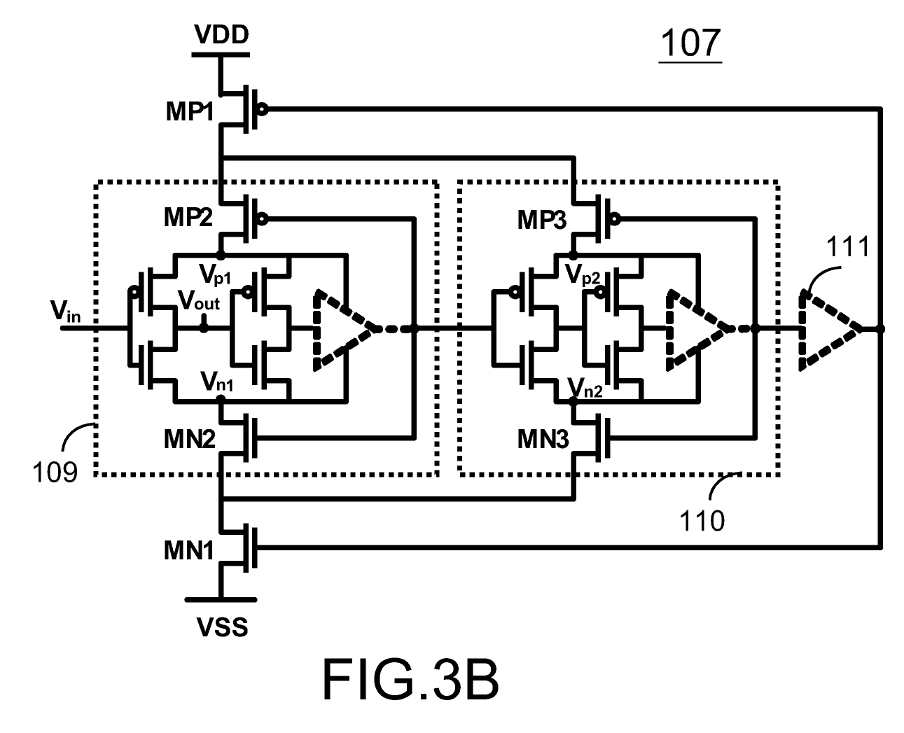

FIG. 3A is a schematic circuit diagram illustrating the exemplary hysteresis delay unit 107 in accordance with the present invention. Referring to FIG. 3A, LHDC is designed by the hysteresis delay unit 107 including an inverter chain internally cascade with a header cell MP1 and a footer cell MN1. The internal voltages Vn and Vp are expressed as

$$\{ \begin{matrix}{V}_{n} {\vert}_{MP 1 = ON} = \frac{{V}_{in}}{{R}_{n} + 1} + \frac{{R}_{n} {V}_{SS} + {V}_{t , n} ( {R}_{n} - 1 )}{{R}_{n} + 1} \\ {V}_{p} {\vert}_{MN 1 = ON} = \frac{{V}_{in}}{{R}_{p} + 1} + \frac{{R}_{p} {V}_{DD} - \vert {V}_{t , p} \vert ( {R}_{p} - 1 )}{{R}_{p} + 1}\end{matrix} \qquad ( 1 )$$

Where the Rₙ=(kₙ₁/kₙ₂)^{1/2} and Rₚ=(kₚ₁/kₚ₂)^{1/2} with the transconductance kₙ and kₚ for a NMOS and a PMOS, respectively. The MOS threshold is denoted by Vₜ. It may be found that the node Vₚ is equal to VDD when the transistor MP1 is operated at ON state. As a result, the internal delay chain of a LHDC is equivalently regarded as a voltage scaling with a supply voltage VDD′=VDD−Vₙ|_{MP1=ON} or VDD′=Vₚ−VSS|_{MN1=ON}. Therefore, an inverter propagation delay (tₚ) in the internal delay chain is expressed by the first-order approximation:

$${t}_{p} \approx {\sum }_{s = 0}^{S - 1} \frac{{C}_{L}}{2 {VDD}^{′}} ( \frac{1}{{k}_{p , s}} + \frac{1}{{k}_{n , s}} ) \qquad ( 2 )$$

Where C_{L} is the output loading in each inverter output node. The k_{n,s} and k_{p,s} denote the transconductance in the s-th inverter, and the capital S represents the total number of inverters in the LHDC. Due to the hysteresis property, the LHDC does not cause large short current sink when the input signal behaves a slow rise- or fall-time transition.

FIG. 3B is a schematic circuit diagram illustrating the exemplary hysteresis delay unit 107 in accordance with the present invention. A VLHDC is designed by a nested cascaded LHDC as illustrated in FIG. 3B. The hysteresis is determined by the amount of header cells and foot cells. The static behavior of VLHDC is stated as follows. It is assumed that the input voltage Vᵢₙ has a transition from low to high. Then the input voltage propagates to the output of the level-1 delay block 109. This also turns on the transistor MN2 and disables MP2. When the input transition propagates to the output leve-2 delay block 110, the transistor MN3 is also turned-on. The output signal of the final-level delay block may directly enable the MN1 or turn on the MN1 after an optional buffer delay chain. This may control the propagation delay of an input change. It is noted that the Vₙ₁ and Vₙ₂ are isolated by two transistors cascaded before the MN2 and MN3 are turned on. This implies that the propagation delay in each nested level is balanced. It is advantageous that the signal propagation in each level block can be operated in the lowest VDD′(VDD′=VDD−Vₙ₁ or VDD−Vₙ₂) as long as the threshold voltage is small enough, and guarantees the VLHDC can be nested deeper with each level block performs the similar propagation delays.

For an identical manufacturing process of a conventional delay line, the VLHDC provides several hundreds times cell delay for a minimum size inverter. This is achieved by increasing output rise-time or fall-time and at the same time avoiding large short current sink in the next stage to maintain the low power purpose. On the other hand, as the spirit of the present invention, the purpose of fine tuning delay cell is achieved by the combination of MHDC and SHDC, which may generate a delay several to several tens times large than a minimum-sized inverter

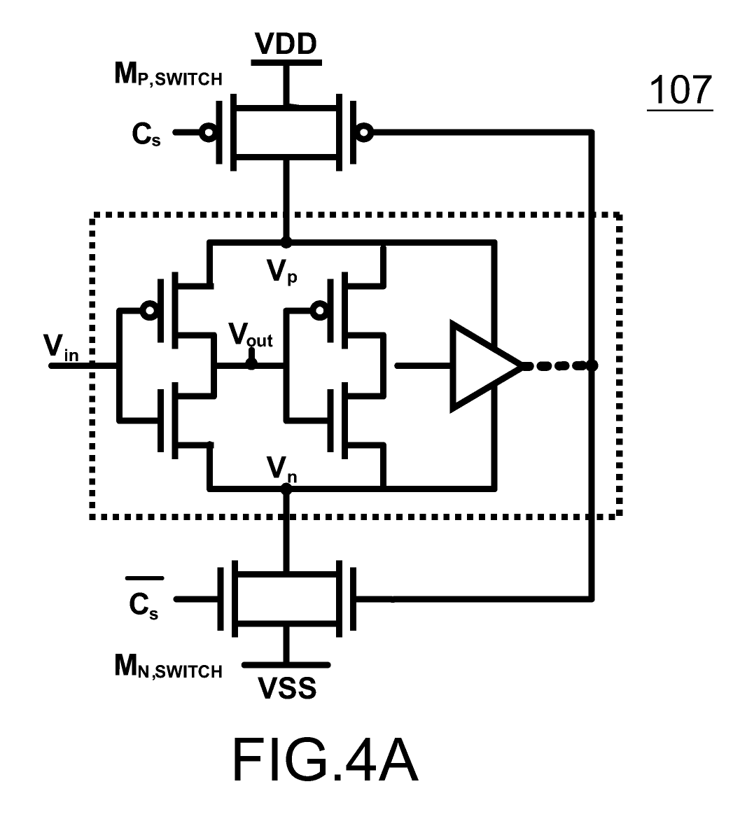

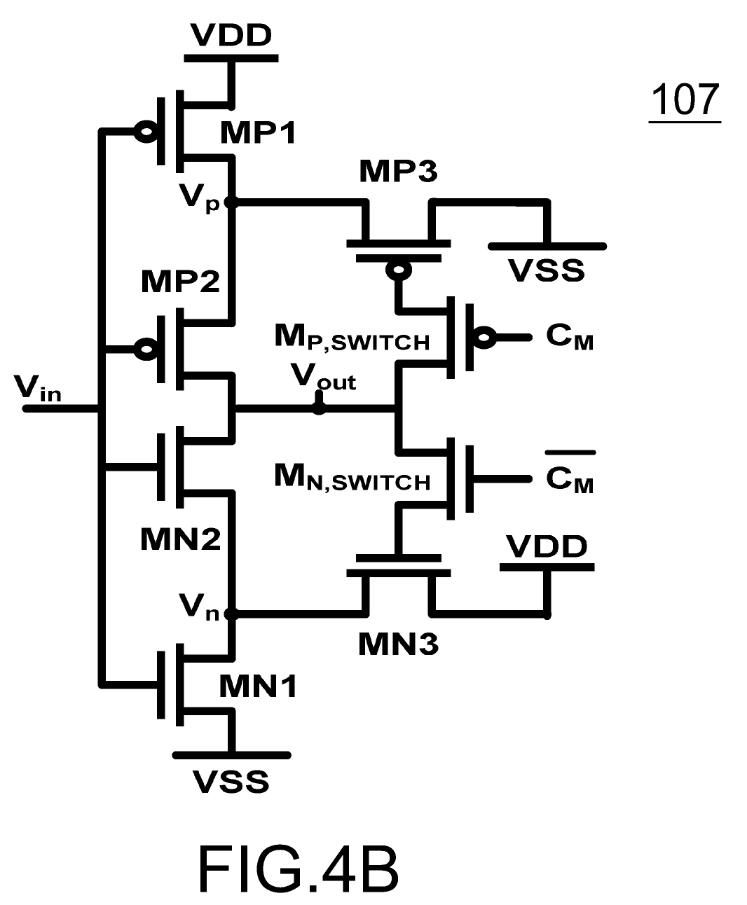

FIG. 4A and FIG. 4B are schematic circuit diagrams illustrating the exemplary MHDC and SHDC of the hysteresis delay unit 107, respectively, according to the present invention. When both transistors M_{P,SWITCH} and M_{N,SWITCH} are in the turn-off state (hysteresis mode), the MHDC and SHDC degenerate to a conventional hysteresis units. As the M_{P,SWITCH} and M_{N,SWITCH} are switched to the turned-on state, a direct charge or discharge path exists in the output node, resulting in a normal inverter behavior (inverter mode). As the transistors are in the turn-off state, the MHDC and SHDC perform the similar propagation delays. The delay analysis may be found from the hysteresis or inverter behavior. When the circuits turn into the hysteresis mode, the internal node voltage and propagation analysis for the MHDC may be found in Eq(3). Furthermore, the Vₙ [symbol] Vₚ of the SHDC is expressed as

$$\{ \begin{matrix}{V}_{n} = {V}_{DD} - {V}_{t , n} - {R}_{n} ( {V}_{in} - {V}_{t , n} ) \\ {V}_{p} = {R}_{p} ( {V}_{DD} + {V}_{t , p} - {V}_{in} ) - {V}_{t , p}\end{matrix} \qquad ( 3 )$$

Where V_{t,n} and V_{t,p} are the threshold voltage of a NMOS and PMOS, respectively. Thus, the delay generation concept by maintaining or destroying the hysteresis property may be applied to provide various combinations. Accordingly, the effective propagation delay of SHDC provides smaller delay than that of MHDC. However, both of them provide small delay value.

Although the present invention has been explained in relation to its preferred embodiment, it is to be understood that other modifications and variation can be made without departing the spirit and scope of the invention as hereafter claimed.

What is claimed is:

1. A delay line, comprising a plurality of hysteresis delay cells connected in series, each of the hysteresis delay cells comprising a hysteresis delay unit, wherein the hysteresis delay units are configured for respectively comparing a first input voltage and a first threshold voltage to determine a first constant output voltage, and comparing a second input voltage and a second threshold voltage to determine a second constant output voltage, and wherein the first threshold voltage is different from the second threshold voltage, and the first constant output voltage is different from the second constant output voltage.

2. A delay line according to claim 1, wherein the hysteresis delay units are identical.

3. A delay line according to claim 2, wherein the hysteresis delay units perform respectively an inverter mode and a hysteresis mode.

4. A delay line according to claim 3, wherein the hysteresis delay units further perform respective a delay time and a resolution which are derived from a time difference in the inverter mode and the hysteresis mode.

5. A delay line according to claim 1, wherein the hysteresis delay units are different.

6. A delay line according to claim 5, wherein the hysteresis delay units perform respectively in an inverter mode and a hysteresis mode.

7. A delay line according to claim 6, wherein the hysteresis delay units further perform respective a delay time and a resolution which are derived from a time difference in the inverter mode and the hysteresis mode.

8. A delay line according to claim 1, further comprising buffer delay chain electrically coupled one of the hysteresis delay units and exterior.

9. A digital phase-locked loops circuit, comprising a clock generator, a phase frequency detector, a frequency generator, a controller and a digital control delay line electrically coupled with each other, wherein the improvement comprises:
the digital control delay line comprising a plurality of hysteresis-based devices coupled with each other in series, wherein the hysteresis-based devices are configured for respectively comparing a first input voltage and a first threshold voltage to determine a first constant output voltage, and comparing a second input voltage and a second threshold voltage to determine a second constant output voltage, and wherein the first threshold voltage is different from the second threshold voltage, and the first constant output voltage is different from the second constant output voltage.

10. A digital phase-locked loops circuit according to claim 9, wherein the hysteresis-based devices comprise respectively a path selector and a hysteresis delay unit electrically coupled with each other, and wherein the path selector receives an output of the phase frequency detector which is derived from a feedback signal of the digital control delay line through the frequency divider.

11. A digital phase-locked loops circuit according to claim 9, wherein the hysteresis delay units are identical.

12. A digital phase-locked loops circuit according to claim 9, wherein the hysteresis delay units are different.

13. A digitally-controlled oscillator, comprising a delay line including a plurality of hysteresis delay cells connected in series, each of the hysteresis delay cells comprising a hysteresis delay unit, wherein the hysteresis delay units are configured for respectively comparing a first input voltage and a first threshold voltage to determine a first constant output voltage, and comparing a second input voltage and a second threshold voltage to determine a second constant output voltage, and wherein the first threshold voltage is different from the second threshold voltage, and the first constant output voltage is different from the second constant output voltage.

14. A digitally-controlled oscillator according to claim 13, wherein the hysteresis delay units are identical.

15. A digitally-controlled oscillator according to claim 14, wherein the hysteresis delay units perform respectively an inverter mode and a hysteresis mode.

16. A digitally-controlled oscillator according to claim 15, wherein the hysteresis delay units further perform respective a delay time and a resolution which are derived from a time difference in the inverter mode and the hysteresis mode.

17. A digitally-controlled oscillator according to claim 13, wherein the hysteresis delay units are different.

18. A digitally-controlled oscillator according to claim 17, wherein the hysteresis delay units perform respectively an inverter mode and a hysteresis mode.

19. A digitally-controlled oscillator according to claim 18, wherein the hysteresis delay units further perform respective a delay time and a resolution which are derived from a time difference in the inverter mode and the hysteresis mode.

20. A digitally-controlled hysteresis loops circuit, comprising a clock generator, a phase frequency detector, a frequency generator, a controller and a digital control delay line electrically coupled with each other, wherein the improvement comprises:
the digital control delay line comprising a plurality of hysteresis-based devices coupled with each other in series, wherein the hysteresis-based devices are configured for respectively comparing a first input voltage and a first threshold voltage to determine a first constant output voltage, and comparing a second input voltage and a second threshold voltage to determine a second constant output voltage, and wherein the first threshold voltage is different from the second threshold voltage, and the first constant output voltage is different from the second constant output voltage.

21. A digitally-controlled hysteresis loops circuit according to claim 20, wherein the hysteresis-based devices comprise respectively a path selector and a hysteresis delay unit electrically coupled with each other, and wherein the path selector receives an output of the phase frequency detector which is derived from a feedback signal of the digital control delay line through the frequency divider.

22. A digitally-controlled hysteresis loops circuit according to claim 20, wherein the hysteresis delay units are identical.

23. A digitally-controlled hysteresis loops circuit according to claim 22, wherein the hysteresis delay units perform respectively an inverter mode and a hysteresis mode.

24. A digitally-controlled hysteresis loop circuit according to claim 20, wherein the hysteresis delay units further perform respective a delay time and a resolution which are derived from a time difference in the inverter mode and the hysteresis mode.

25. A digitally-controlled hysteresis loop circuit according to claim 20, wherein the hysteresis delay units are different.

26. A digitally-controlled hysteresis loop circuit according to claim 25, wherein the hysteresis delay units perform respectively an inverter mode and a hysteresis mode.

27. A digitally-controlled hysteresis loop circuit according to claim 26, wherein the hysteresis delay units further perform respective a delay time and a resolution which are derived from a time difference in the inverter mode and the hysteresis mode.
